(19) United States
(12) Patent Application Publication
(10) Pub. No.: US 2016/0143195 A1
(43) Pub. Date: May 19, 2016

(54) IMMOBILIZED MELANIN AND ITS CHEMICAL DERIVATIVES FOR THE HARVESTING OR SHIELDING OF HIGH ENERGY ELECTROMAGNETIC RADIATION

(71) Applicants: Ite Chen, Washington Township, NJ (US); Tara Anne Cronin, Washington Township, NJ (US); David Pernas, Staten Island, NY (US)

(72) Inventors: Ite Chen, Washington Township, NJ (US); Tara Anne Cronin, Washington Township, NJ (US); David Pernas, Staten Island, NY (US)

(21) Appl. No.: 14/542,024

(22) Filed: Nov. 14, 2014

(51) Int. Cl. H05K 9/00; C09D 5/24; C08F 226/06; C09D 139/04; C08F 214/26; C25C 7/02; C09D 127/22

(52) U.S. Cl. CPC H05K 9/0088; C25C 7/02; C09D 5/24; C09D 127/22; C09D 139/04; C08F 214/265; C08F 226/06

(57) ABSTRACT

A method and apparatus for a photocatalytic and electrolytic electromagnetic shielding and responsive polymer includes in various aspects one or more electromagnetic shielding and responsive polymers, a method for forming a electromagnetic shielding and responsive polymer, an electrolytic electromagnetic energy dispersion cell, and a reaction method, as well as applications.

The priority of U.S. application Ser. No. 61/904414, entitled, “IMMOBILIZED MELANIN AND ITS CHEMICAL DERIVATIVES FOR THE HARVESTING OR SHIELDING OF HIGH ENERGY ELECTROMAGNETIC RADIATION.” filed Nov. 14, 2013, in the name of the inventor Ite Chen is hereby claimed pursuant to 35 U.S.C. §119(e). This application is commonly assigned herewith and is also hereby incorporated for all purposes as if set forth verbatim herein.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND

This section of this document introduces information about and/or from the art that may provide context for or be related to the subject matter described herein and/or claimed below. It provides background information to facilitate a better understanding of the various aspects of the claimed subject matter. This is therefore a discussion of “related” art. That such art is related in no way implies that it is also “prior” art. The related art may or may not be prior art. The discussion in this section of this document is to be read in this light, and not as admissions of prior art.

Some common industrial processes involve the conversion of a gas or components of a gaseous mixture into another gas, which is relevant to an embodiment of the subject matter described below. These types of processes are performed at high pressures and temperatures. Operational considerations such as temperature and pressure requirements frequently make these types of processes energy inefficient and costly. The industries in which these processes are used therefore spend a great deal of effort in improving the processes with respect to these kinds of considerations. The art, however, is always receptive to improvements or alternative means, methods and configurations. Therefore the art will well receive the technique described herein.

### SUMMARY

In a first aspect, a electromagnetic shielding and responsive polymer comprises: a first component selected from melanin and its derivatives; and a second component bonded to the first component, wherein the second component is selected from fluorinated sulfonic acid based polymers, other polymers or monomers and combinations thereof.

In a second aspect, a method of forming a electromagnetic shielding and responsive polymer comprising: contacting a first component selected from melanin and its derivatives with a second component selected from fluorinated sulfonic acid based polymers, other polymers or monomers and combinations thereof.

In a, an electrolytic cell, comprises: at least one reaction chamber into which, during operation, aqueous electrolyte or solid-state semiconductor board with electronic components and a gaseous feedstock are introduced, wherein the gaseous feedstock comprises a gas, and a pair of reaction electrodes are disposed within a reaction chamber. At least one of the reaction electrodes includes a electromagnetic shielding and responsive polymer comprising: a first component selected from melanin and its derivatives; and a second component bonded to the first component, wherein the second component is selected from fluorinated sulfonic acid based polymers, other polymers or monomers and combinations thereof; wherein the electromagnetic shielding and responsive polymer, the aqueous electrolyte or solid-state semiconductor board with electronic components and the gaseous feedstock, define a three-phase interface.

In a fourth aspect, a method comprises: contacting a gaseous feedstock, an aqueous electrolyte or solid-state semiconductor board with electronic components, and a electromagnetic shielding and responsive polymer in a reaction area, the electromagnetic shielding and responsive polymer comprising a first component selected from melanin and its derivatives; and a second component bonded to the first component, wherein the second component is selected from fluorinated sulfonic acid based polymers, other polymers or monomers and combinations thereof; and activating the gaseous feedstock in an aqueous electrochemical reaction in the reaction area to yield a product.

In a fifth aspect, a electromagnetic shielding and responsive polymer comprises: a first component selected from melanin and its derivatives; and a second component selected from fluorinated sulfonic acid based polymers, other polymers or monomers and combinations thereof, wherein the electromagnetic shielding and responsive polymer comprises a blend of the first component and the second component, a multi-layer film of the first component and the second component, a membrane formed from incorporating the first component into a membrane formed from the second component or a membrane formed from a blend of the first component and second component.

The above presents a simplified summary of the presently disclosed subject matter in order to provide a basic understanding of some aspects thereof. The summary is not an exhaustive overview, nor is it intended to identify key or critical elements to delineate the scope of the subject matter claimed below. Its sole purpose is to present some concepts in a simplified form as a prelude to the more detailed description set forth below.

### DETAILED DESCRIPTION

Illustrative embodiments of the subject matter claimed below will now be disclosed. In the interest of clarity, not all features of an actual implementation are described in this specification. It will be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort, even if complex and time-consuming, would be a routine undertaking for those of ordinary skill in the art having the benefit of this disclosure.

The presently disclosed technique provides an electromagnetic shielding and responsive polymer, methods for manufacturing same, and uses therefore. The electromagnetic shielding and responsive polymer described in further detail herein is photocatalytic, electrocatalytic or both photocatalytic and electrocatalytic. As used herein, the term “photocatalytic” refers to the alteration of the rate of a chemical reaction by light or other electromagnetic radiation while the term “electrocatalytic” refers to a mechanism which produces a speeding up of half-cell reactions at electrode surfaces.

The electromagnetic shielding and responsive polymer generally includes a first component and a second component bonded to the first component. The first component, in various embodiments, may be selected from melanin and its derivatives, In some embodiments, a protein enzyme such as a plant enzyme or a metabolic enzyme may be combined with melanin. A non-limiting plant enzyme suitable for implementation is a photosystem enzyme, including but not limited to, melanin, ribulose-1,5-bisphosphate carboxylase oxygenase (RuBisCO) and derivatives thereof. Non-limiting derivatives include, by way of example, melanin and azurite. Other embodiments may use metabolic enzymes. Non-limiting, exemplary metabolic enzymes include hemoglobin, ferritin, co-enzyme Q and derivatives thereof. Still other embodiments may use metabolic factors. These may include, but are not limited to, vitamins, such as B12 and its derivatives, although other vitamins and metabolic factors may be used. And still other embodiments may use an organometallic component, such as a porphyrin complexed with a metal. The metal may include a variety of metals, such as ferromagnetic metals, including cobalt, iron, nickel and combinations thereof. One suitable porphyrin complexed with a metal is cobalt tetramethoxyphenylporphyrin and derivatives thereof, although other porphyrins and other organometallic components may also be suitable.

The second component generally includes an electroconductive polymer. The electroconductive polymer may include, depending on the embodiment, a fluorinated sulfonic acid based polymer or polyalinine. One suitable fluorinated sulfonic acid based polymer is a sulfonated tetrafluoroethylene based fluoropolymer-copolymer. One particular sulfonated tetrafluoroethylene based fluoropolymer-copolymer suitable for use is sold under the trade name NAFION® by DuPont. Thus, in some embodiments, the second component may be an ion exchange resin such as NAFION®. However, other suitable electroconductive polymers may become apparent to those skilled in the art having the benefit of this disclosure and may be used in alternative embodiments.

The second component may be bonded to the first component via any method suitable for bonding such components to one another. However, such bonding process generally results in a bond that does not dissociate upon immersion or contact with water. For example, the bond may be ionic, covalent or combinations thereof. While techniques for manufacturing the electromagnetic shielding and responsive polymer are presented herein, it is understood that other techniques may be used. Similarly, while some exemplary uses are disclosed and claimed herein, the electromagnetic shielding and responsive polymer may be applied to other uses.

The electromagnetic shielding and responsive polymer may be formed in a variety of manners. For example, the electromagnetic shielding and responsive polymer may include a blend of the first component and the second component. Alternatively, the electromagnetic shielding and responsive polymer may include a multi-layer film of the first component and the second component. In one or more embodiments, the first component may be incorporated into a membrane formed from the second component. In yet another embodiment, the first component and the second component are blended and formed into a membrane.

In one or more embodiments, the electromagnetic shielding and responsive polymer includes from 20 wt. % to 80 wt. % first component and from 20 wt. % to 80 wt. % second component. For example one may use 5 grams of melanin mixed with 20 grams of NAFION®, 10 grams of ferritin with 20 grams of NAFION® or 20 grams of B12 mixed with 5 grams of NAFION®.

In one or more embodiments, the electromagnetic shielding and responsive polymer is bound to a support material to form a supported electromagnetic shielding and responsive polymer. Typical support materials may include talc, inorganic oxides, clays and clay minerals, ion-exchanged layered components, diatomaceous earth components, zeolites or a resinous support material, such as a polyolefin, for example. Specific inorganic oxides include silica, alumina, magnesia, titania and zirconia, for example. In one or more embodiments, the support material includes a nanoparticulate material. The term “nanoparticulate material” refers to a material having a particle size smaller than 1,000 nm. Exemplary nanoparticulate materials include, but are not limited to, a plurality of fullerene molecules (i.e., molecules composed entirely of carbon, in the form of a hollow sphere (e.g., buckyballs), ellipsoid or tube (e.g., carbon nanotubes), a plurality of quantum dots (e.g., nanoparticles of a semiconductor material, such as chalcogenides (selenides or sulfides) of metals like cadmium or zinc (CdSe or ZnS, for example)), graphite, a plurality of zeolites, or activated carbon. In addition to the non-limiting, exemplary supports listed above, any electromagnetic shielding and responsive polymer support known to those skilled in the art may be used depending upon implementation-specific design considerations. Accordingly, other embodiments may employ other supports for the electromagnetic shielding and responsive polymer.

In another aspect, the technique presents a process for forming the electromagnetic shielding and responsive polymer described previously herein. One particular embodiment of the process includes contacting the first component with the second component. Such contact may include a variety of processes, such as blending the components or forming a multi-layer film with the components, for example. One particular embodiment includes blending the first component with the second component. In one or more embodiments, the first component and the second component are contacted in a solution of alcohol and water. The solution may include from 3 wt. % to 97 wt. % alcohol and from 3 wt. % to 97 wt. % water, for example. The contact may last for a time sufficient to bond or blend the first and second component. For example, the contact may last for a time of from 30 minutes to 24 hours.

The resulting mixture may be dried to yield a crystalized electromagnetic shielding and responsive polymer. The act of drying the solution mentioned above may be performed by permitting the solution to dry by evaporation. However, some embodiments may facilitate or accelerate drying by heating the solution. However, care should be taken to avoid damaging the solution components with the heat. Thus, embodiments which include heating in the drying should heat the solution to a temperature below the breakdown or boiling temperatures of the components, i.e., the first and second component, alcohol, and water.

In one particular embodiment, the first component and the second component are blended in substantially equal molar amounts. However, this is product dependent and not all embodiments will mix in equal molar amounts. Alternative embodiments may employ different ratios for the mixture to adjust for kinetics, electromagnetic shielding and responsive polymer lifetime, and yields of products. For example, one or more embodiments may include contacting the first component and the second component in a molar ratio of from 0.8:1 to 1.2:1. Some embodiments contact and crystalize the components as described above and then add water to the crystallized electromagnetic shielding and responsive polymer to test the electromagnetic shielding and responsive polymer for water solubility. If the crystallized electromagnetic shielding and responsive polymer is still water soluble, the crystallized electromagnetic shielding and responsive polymer can be reconstituted with an alcohol/water mixture along with further first and second component and the process repeated as described above until the crystallized electromagnetic shielding and responsive polymer is no longer water soluble.

Preparing the mixture in solution may also find variation across embodiments. In one embodiment, preparing the mixture in solution includes dissolving the mixture with the alcohol and water. In another embodiment, preparing the mixture in solution includes dispersing the mixture in a colloidal suspension in the alcohol and water. Those in the art having the benefit of this disclosure may find still other alternatives for the preparation of the mixture in solution.

Some embodiments may reconstitute the crystallized polymer for reasons other than testing for water solubility. For example, in some embodiments, the crystallized polymer may be reconstituted for the purpose of fabricating it into a membrane or as otherwise described herein. In this case, the crystallized polymer may be reconstituted by, for example, adding pure alcohol or another non-water based solvent such as napthalene or hexane. The use of such membranes is helpful in implementing some of the end uses described further below.

In a third aspect, the electromagnetic shielding and responsive polymer as described above may be implemented in an electrolytic cell. Such an electrolytic cell may comprise at least one reaction chamber and a pair of reaction electrodes. During operation, aqueous electrolyte or solid-state semiconductor board with electronic components and a gaseous feedstock are introduced into at least one chamber, the gaseous feedstock comprising a gas. The pair of reaction electrodes is disposed within the reaction chamber. At least one of the reaction electrodes includes the electromagnetic shielding and responsive polymer as described above adapted to catalyze reaction between the electrolyte and the gaseous feedstock.

In some embodiments, the electromagnetic shielding and responsive polymer, in conjunction with the aqueous electrolyte or solid-state semiconductor board with electronic components and the gaseous feedstock, defines a three-phase interface. However, the presently disclosed technique is not so limited. The electromagnetic shielding and responsive polymer will also operate in liquid/liquid and gas/gas reactions. With respect to gas/gas reactions, these will be between gas phase reactants.

The aqueous electrolyte or solid-state semiconductor board with electronic components may comprise any ionic substance that dissociates in aqueous solution. In various embodiments, the aqueous electrolyte or solid-state semiconductor board with electronic components is selected from potassium chloride, potassium bromide, potassium iodide, hydrogen chloride, magnesium sulfate, sodium chloride, sulfuric acid, sea salt, or brine. However, other embodiments may employ other aqueous electrolyte or solid-state semiconductor board with electronic components.

The gas of the gaseous feedstock may comprise a non-polar gas, a carbon oxide, or a mixture of the two. Suitable non-polar gases include a hydrocarbon gas. Suitable carbon oxides include carbon monoxide, carbon dioxide, or a mixture of the two. These examples are non-limiting and other non-polar gases and carbon oxides may be used in other embodiments. In some embodiments, the gaseous feedstock comprises one or more greenhouse gases.

In a fourth aspect, an electrolytic cell in which the electromagnetic shielding and responsive polymer has been deployed as described above may be used to implement one or more methods for chain modification of hydrocarbons and organic components. The method comprises contacting a gaseous feedstock including a gas, an aqueous electrolyte or solid-state semiconductor board with electronic components, and the electromagnetic shielding and responsive polymer in a reaction area. The gas is then activated in an aqueous electrochemical reaction in the reaction area to yield a product.

As described above, the aqueous electrolyte or solid-state semiconductor board with electronic components may comprise any ionic substance that dissociates in aqueous solution. In various embodiments, the aqueous electrolyte or solid-state semiconductor board with electronic components is selected from potassium chloride, potassium bromide, potassium iodide, hydrogen chloride, magnesium sulfate, sodium chloride, sulfuric acid, sea salt, or brine. However, other embodiments may employ other aqueous electrolyte or solid-state semiconductor board with electronic components.

Also as described above, the gas of the gaseous feedstock may comprise a non-polar gas, a polar gas, a carbon oxide, or a mixture of the two. Suitable non-polar gases include a hydrocarbon gas. Suitable carbon oxides include carbon monoxide, carbon dioxide, or a mixture of the two. These examples are non-limiting and other gases and inorganic gases may be used in other embodiments. In some embodiments, the gaseous feedstock comprises one or more greenhouse gases.

The presently disclosed technique is, in this particular embodiment, a process for converting electromagnetic energy into electrical and chemical energy to disperse or utilize the energy in military, medical, and chemical applications, as well as others not limited to the previous three.

This aqueous electrochemical reaction includes a reaction that proceeds at room temperature and pressure, although higher temperatures and pressures may be used. In general, temperatures may range from −10° C. to 240° C., or from −10° C. to 1000° C., and pressures may range from 0.1 ATM to 10 ATM, or from 0.1 ATM to 100 ATM. The process generates reactive activated gases through the reaction on the reaction electrodes. On the reaction electrode, the production of activated gases occurs.

Exemplary liquid ionic substances include, but are not limited to, polar organic components, such as glacial acetic acid, alkali or alkaline earth salts, such as halides, sulfates, sulfites, carbonates, nitrates, or nitrites. The electrolyte may therefore be, depending upon the embodiment, magnesium sulfate (MgS), sodium chloride (NaCl), sulfuric acid (H₂SO₄), potassium chloride (KCl), hydrogen chloride (HCl), hydrogen bromide (HBr), hydrogen fluoride (HF), potassium chloride (KCl), potassium bromide (KBr), and potassium iodide (KI), or any other suitable electrolyte and acid or base known to the art.

The pH of the electrolyte may range from −4 to 14 and concentrations of between 0M and 3M inclusive may be used. Some embodiments may use water to control pH and concentration, and such water may be industrial grade water, brine, seawater, or even tap water. The liquid ion source, or electrolyte, may comprise essentially any liquid ionic substance.

The voltage level can be used to control the resulting product. A voltage of 0.01V may result in a methanol product whereas a 0.5V voltage may result in butanol as well as higher alcohols such as dodecanol or simply the production of hydroxide ions. A voltage of 2 volts may results in the production of ethylene or polyvinyl chloride precursors. These specific examples may or may not be reflective of the actual product yield and are meant only to illustrate how a product produced can be altered with a change in voltage.

Returning now to the third aspect, additional attention will now be directed to the electrolytic cell. As noted above, a reaction chamber can be fabricated from conventional materials using conventional fabrication techniques. Notably, the presently disclosed technique may operate at room temperatures and pressures whereas conventional processes are performed at temperatures and pressures much higher. Design considerations pertaining to temperature and pressure therefore can be relaxed relative to conventional practice. However, conventional reactor designs may nevertheless be used in some embodiments.

The electromagnetic shielding and responsive polymer disclosed above, when incorporated into a suitable apparatus, can be used for a wide variety of end uses, such as to deodorize water, to produce alkalizing ions for cancer treatment, to kill tumors, to shield electrical components from electromagnetic radiation, to prevent electromagnetic pulses from knocking out electronics, and other uses.

Note that not all embodiments will manifest all these characteristics and, to the extent they do, they will not necessarily manifest them to the same extent. Thus, some embodiments may omit one or more of these characteristics entirely. Furthermore, some embodiments may exhibit other characteristics in addition to, or in lieu of those described herein.

The phrase “capable of” as used herein is a recognition of the fact that some functions described for the various parts of the disclosed apparatus are performed only when the apparatus is powered and/or in operation. Those in the art having the benefit of this disclosure will appreciate that the embodiments illustrated herein include a number of electronic or electro-mechanical parts that, to operate, require electrical power. Even when provided with power, some functions described herein only occur when in operation. Thus, at times, some embodiments of the apparatus of the invention are “capable of” performing the recited functions even when they are not actually performing them—i.e., when there is no power or when they are powered but not in operation.

The following patent, applications, and publications are hereby incorporated by reference for all purposes as if set forth verbatim herein:

U.S. application Ser. No. 61/904414, entitled, “Immobilized Melanin and its chemical derivatives for the harvesting or shielding of high energy electromagnetic radiation”, filed. Nov. 14, 2013, in the name of the inventor Ite Chen and commonly assigned herewith.

To the extent that any patent, patent application, or other reference incorporated herein by reference conflicts with the present disclosure set forth herein, the present disclosure controls.

What is claimed:

1. A electromagnetic shielding and responsive polymer comprising:
a first component selected from melanin and its derivatives; and a second component bonded to the first component, wherein the second component is selected from fluorinated sulfonic acid based polymers, other polymers or monomers and combinations thereof.

2. The electromagnetic shielding and responsive polymer of claim 1, wherein the electromagnetic shielding and responsive polymer is photocatalytic and electrocatalytic.

3. The electromagnetic shielding and responsive polymer of claim 1, wherein one or more additional protein enzymes are added to the polymer, which are selected from compounds such as porphyrins, chlorophyll, photosystem enzymes, ribulose-1,5-bisphosphate carboxylase oxygenase (RuBisCO), melanin, azurite, hemoglobin, ferritin, co-enzyme Q, vitamins, or derivatives thereof and combinations thereof, including but not limited to complexes with ferromagnetic metals.

4. The electromagnetic shielding and responsive polymer of claim 1, wherein the fluorinated sulfonic acid based polymer comprises sulfonated tetrafluoroethylene based fluoropolymer-copolymer.

5. The electromagnetic shielding and responsive polymer of claim 1, wherein the electromagnetic shielding and responsive polymer is selective to gases to disperse electromagnetic energy.

6. The electromagnetic shielding and responsive polymer of claim 1 further comprising a support material.

7. The electromagnetic shielding and responsive polymer of claim 6, wherein the support material comprises a nanoparticle mixture.

8. The electromagnetic shielding and responsive polymer of claim 6, wherein the support material is selected from a plurality of fullerene molecules, a plurality of quantum dots, graphite, a plurality of zeolites, and activated carbon.

9. A method of forming a electromagnetic shielding and responsive polymer comprising:
contacting a first component selected from melanin and its derivatives with a second component selected from fluorinated sulfonic acid based polymers, other polymers or monomers and combinations thereof that form a monolayered or multilayered paint.

10. The method of claim 9, wherein the first component contacts the second component in a molar ratio between 1:120 to 120:1.

11. The method of claim 9, further comprising drying a solvent based solution to yield a crystallized electromagnetic shielding and responsive polymer.

12. The method of claim 11, wherein the contacting comprises dispersing the first and second components in a colloidal suspension in the solution.

13. The method of claim 11 further comprising forming a membrane from the electromagnetic shielding and responsive polymer.

14. An electrolytic cell that disperses electromagnetic energy, comprising:
at least one reaction chamber into which, during operation, aqueous electrolyte or solid-state semiconductor board with electronic components and a gaseous feedstock are introduced, wherein the gaseous feedstock comprises a gas; and
a pair of reaction electrodes disposed within the reaction chamber, at least one of the reaction electrodes including a electromagnetic shielding and responsive polymer comprising:
a first component selected from melanin and its derivatives; and
a second component bonded to the first component, wherein the second component is selected from fluorinated sulfonic acid based polymers, other polymers or monomers and combinations thereof;
wherein the electromagnetic shielding and responsive polymer, the aqueous electrolyte or solid-state semiconductor board with electronic components and the gaseous feedstock, define a three-phase interface.

15. The electrolytic cell of claim 14, wherein the electromagnetic energy dispersant is a gas.

16. The application of the membrane of claim 1 for military, medical, and electrical component shield.

17. The application of claim 1 for military, medical and electrical component shielding.

18. The application of claim 1 for military, medical and electrical component shielding.
